(19) United States
(12) Patent Application Publication
(10) Pub. No.: US 2016/0212880 A1
(43) Pub. Date: Jul. 21, 2016

(54) AIR GUIDE COOLING MODULE AND AIR GUIDE HEAT SINK

(71) Applicant: AIC INC., Taoyuan Hsien (TW)

(72) Inventors: Wei-Te WANG, Taoyuan Hsien (TW); Ming-Hung TSAI, Taoyuan Hsien (TW); Yan-Yu LEE, Taoyuan Hsien (TW)

(21) Appl. No.: 14/600,178

(22) Filed: Jan. 20, 2015

(51) Int. Cl. H05K 7/20

(52) U.S. Cl. CPC H05K 7/20145; H05K 7/20154

(57) ABSTRACT

In an air guide heat sink and an air guide cooling module, the air guide heat sink includes a base and a pair of U-shaped air guide members. The base is connected with a plurality of fins. The pair of U-shaped air guide members is detachably connected to the base. The pair of U-shaped air guide members and the base surround and form an air guide channel. Each of the U-shaped air guide members has a vertical plate and two ends of the vertical plate extend towards a direction away from the base and form two horizontal plates. Thereby, the air guide cooling module and the air guide heat sink may be installed on the motherboard with electronic components densely disposed thereon. Additionally, the air guide cooling module and the air guide heat sink may receive maximum airflow.

### TECHNICAL FIELD

The disclosure relates to a heat sink, more particularly to an air guide cooling module and an air guide heat sink.

### BACKGROUND

As technology advances, more and more electronic components may be arranged on a motherboard. An industry computer, for example, is with multiple CPUs (Central Processing Units) arranged side by side and installed thereon as well as multiple memory slots arranged on two sides of each CPU. This improves the performance and expandability of the motherboard.

As today's motherboards are made quite small, CPUs and memory slots are arranged very densely. This results in problems of heat dissipation regarding to CPUs, which affect its operation negatively. Hence, it is important to find a way to install a heat sink on the motherboard with electronic components densely arranged thereon.

The objective of the disclosure is to provide an improved design capable of solving the problems mentioned above.

### SUMMARY

One goal of the disclosure is to provide an air guide cooling module and an air guide heat sink, in which the base and the U-shaped air guide members can be assembled together and disassembled from each other. This enables the air guide cooling module and the air guide heat sink to be installed on the motherboard with electronic components that are densely disposed thereon. Additionally, the base and the U-shaped air guide member can guide airflow into the air guide channel such that the air guide cooling module and the air guide heat sink may receive maximum airflow.

To reach this goal, the disclosure provides an air guide heat sink comprising a base and a pair of U-shaped air guide members. The base is connected with a plurality of fins. The pair of U-shaped air guide members is detachably connected to the base. The pair of U-shaped air guide members and the base surround and form an air guide channel. Each of the U-shaped air guide members has a vertical plate and two ends of the vertical plate extend towards a direction away from the base and form two horizontal plates.

Moreover, the disclosure provides an air guide cooling module comprising two bases and a pair of U-shaped air guide members. The two bases are arranged side by side, wherein one of the two bases is connected with a plurality of first fins while the other is connected with a plurality of second fins. The pair of U-shaped air guide members is detachably connected to the base. The pair of U-shaped air guide members and the base surround and form an air guide channel. Each of the U-shaped air guide members has a vertical plate and two ends of the vertical plate extend towards a direction away from the base and form two horizontal plates.

### BRIEF DESCRIPTION OF THE DRAWINGS

The disclosure will become more fully understood from the detailed description and the drawings given herein below for illustration only, and thus does not limit the disclosure, wherein:

FIG. 1 is a perspective view of an air guide heat sink according to the first embodiment of the disclosure;

FIG. 2 is an exploded view of the air guide heat sink according to the first embodiment of the disclosure;

FIG. 3 is a top view of the air guide heat sink according to the first embodiment of the disclosure;

FIG. 4 is a sectional view of an air guide heat sink according to the second embodiment of the disclosure;

FIG. 5 is a sectional view of an air guide heat sink according to the third embodiment of the disclosure;

FIG. 6 is a sectional view of an air guide heat sink according to the fourth embodiment of the disclosure;

FIG. 7 is a sectional view of an air guide heat sink according to the fifth embodiment of the disclosure;

FIG. 8 is a sectional view of an air guide heat sink according to the sixth embodiment of the disclosure;

FIG. 9 is a sectional view of an air guide heat sink according to the seventh embodiment of the disclosure;

FIG. 10 is an exploded view of an air guide cooling module according to the first embodiment of the disclosure;

FIG. 11 is a perspective view of the air guide cooling module according to the first embodiment of the disclosure;

FIG. 12 is a schematic view of a use state of the air guide cooling module according to the first embodiment of the disclosure;

FIG. 13 is a schematic view of another use state of the air guide cooling module according to the first embodiment of the disclosure;

FIG. 14 is a schematic view of still another use state of the air guide cooling module according to the first embodiment of the disclosure;

FIG. 15 is a schematic view of a use state of an air guide cooling module according to the second embodiment of the disclosure; and

FIG. 16 is a schematic view of a use state of an air guide cooling module according to the third embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

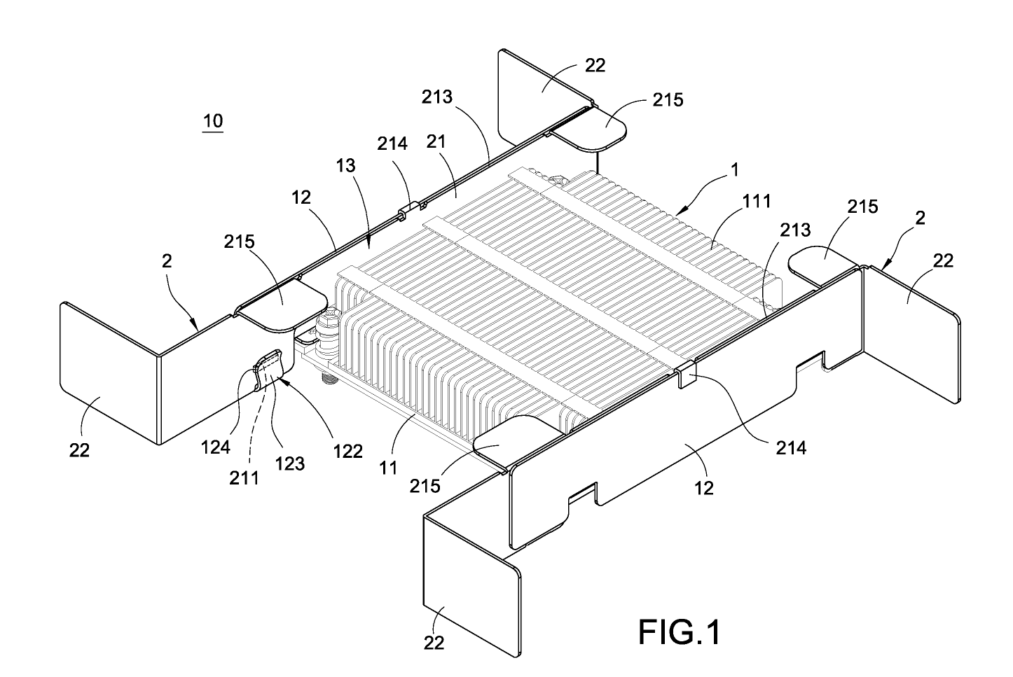

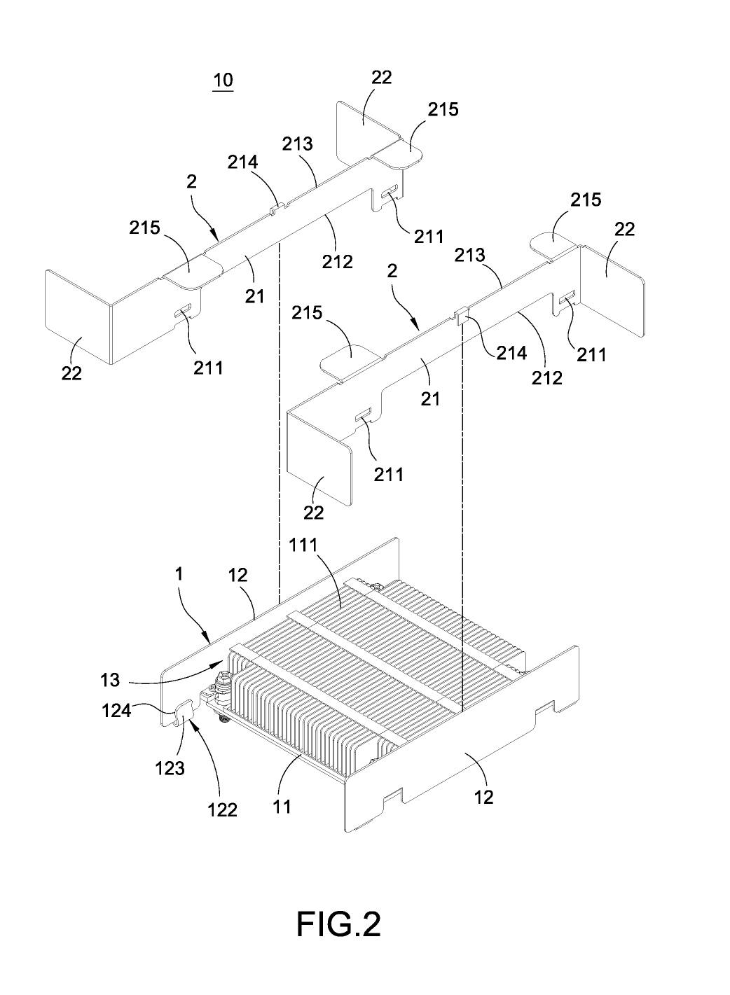

Referring to FIG. 1 to FIG. 3, the disclosure provides an air guide heat sink mainly comprising a base 1 and a pair of U-shaped air guide members 2.

The base 1 comprises a thermal plate 11 and a pair of air guide plates 12 fixed to and connected to opposite two sides of the thermal plate 11. The thermal plate 11 and the two air guide plates 12 form an air guide channel 13 between them. The thermal plate 11 is connected with a plurality of fins 111 and each of the air guide plates 12 has a connection portion 122.

Specifically, each connection portion 122 comprises one or multiple elastic pieces 123 which extend from the air guide plate 12 and are folded. Each elastic piece 123 has a protruding portion 124 and is arranged on the inner side of the air guide plate 12. That is, each elastic piece 123 is arranged on one side of the air guide plate 12 near the fins 111.

The pair of the U-shaped air guide members 2 is detachably connected to the base 1. The two U-shaped air guide members 2 and the base 1 surround and form an air guide channel 13. Each U-shaped air guide member 2 has a vertical plate 21 and two horizontal plates 22 bending and extending from two ends of the vertical plate 21 towards a direction away from the base 1. Each vertical plate 21 and each connection portion 122 are connected with each other.

Furthermore, one or multiple fastening grooves 211 are formed on each vertical plate 21. Each protruding portion 124 and each fastening groove 211 are fastened with each other while each vertical plate 21 has a bottom end 212 and a top end 213. Each fastening groove 211 is formed near the bottom end. Each top end 213 extends towards the air guide plate 12 and folds to form one or multiple hooks 214. Each hook 214 and each air guide plate 12 are fastened with each other. The angle θ1 between each vertical plate 21 and the horizontal plate 22 ranges from 90 degrees to 150 degrees. In this embodiment, the optimal angle θ1 between each vertical plate 21 and the horizontal plate 22 is 90 degrees.

Moreover, each top end 213 extends towards the inner side of each of the vertical plates 21 and forms a handle portion 215, namely each top end 213 extending towards the fins 111 to form the handle portion 215.

The assembly of the air guide heat sink 100 involves the base 1 connected with multiple fins 111; the U-shaped air guide member 2 is detachably connected to the base 1; the two U-shaped air guide members 2 and the base 1 surround and form an air guide channel 13; each U-shaped air guide member 2 has one vertical plate 21 and two horizontal plates 22 bending and extending from two ends of the vertical plate 21 towards a direction away from the base 1. Thereby, the base 1 and the U-shaped air guide member 2 may be assembled together and be separated from each other so that the air guide heat sink 10 may be installed on the motherboard with electronic components densely disposed thereon. Additionally, the base 1 and the U-shaped air guide member 2 can guide airflow into the air guide channel 13 such that the air guide heat sink 10 may receive maximum airflow. This improves the efficiency of heat dissipation of the air guide heat sink 10.

Further, the shape of the air guide heat sink 10 is similar to a plate so the air guide heat sink 10 is thin enough to be fixed to most places (e.g. a motherboard or a case).

Each top end 213 extends towards the air guide plate 12 and folds to form a hook 214. Each hook 214 and each air guide plate 12 are fastened witch each other, thereby improving the stability of the U shaped air guide member 2 installed on the air guide plate 12

Also, each top end 213 extends towards the inner side of each of the vertical plates 21 to form the handle portion 215 for users to hold. This makes the assembly and disassembly of the U-shaped air guide member 2 and the air guide plate 12 even easier.

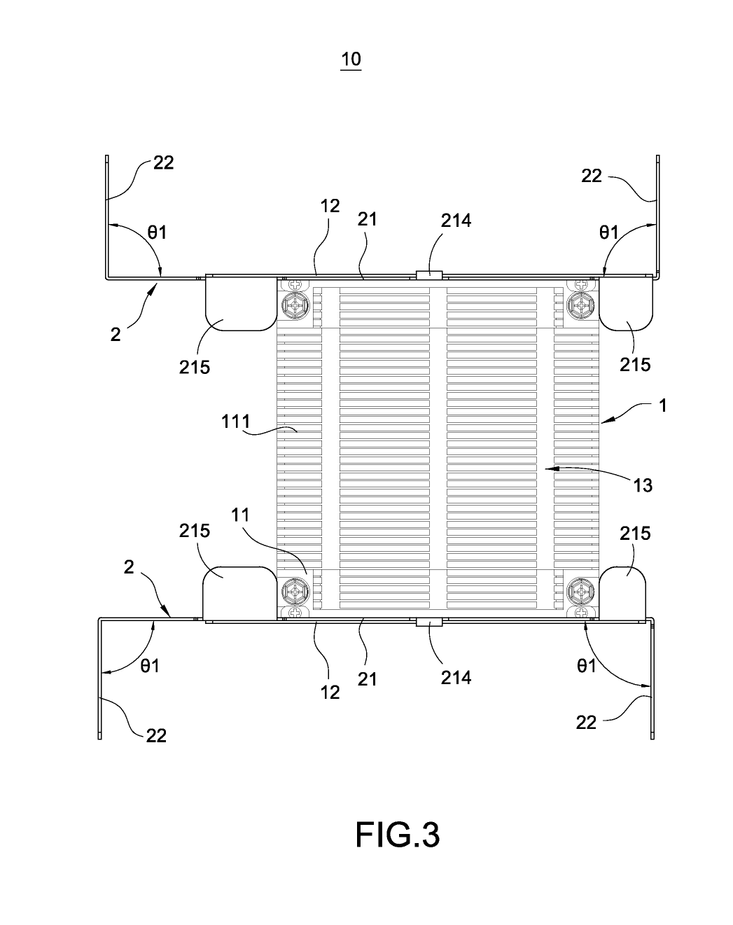

As seen in FIG. 3 to FIG. 6, the air guide heat sinks 10 of the second, third and fourth embodiments are similar to that of the first embodiment except that the air guide heat sinks 10 further comprises a heat pipe 3.

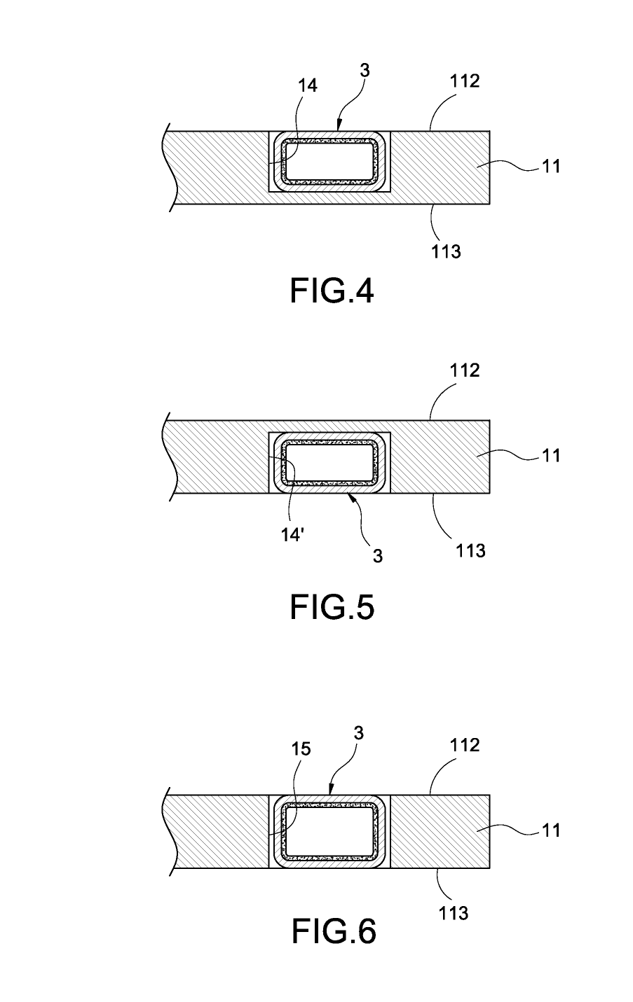

Specifically, in the air guide heat sink 10 of the second embodiment as shown in FIG. 4, the thermal plate 11 has a top surface 112. A recess 14 is formed on the top surface 112. The heat pipe 3 is mounted on the recess 14. As seen in FIG. 5, in the air guide heat sink 10 of the third embodiment, the thermal plate 11 has a bottom surface 113 and a recess 14′ is formed on the bottom surface. The heat pipe 3 is mounted on the recess 14′. In the air guide heat sink 10 of the fourth embodiment shown in FIG. 6, the thermal plate 11 has a top surface 112 and a bottom surface 113. A through groove 15 penetrating the top surface 112 and the bottom surface 113 is formed on the thermal plate 11. The heat pipe 3 is mounted on the through groove 15. Since the heat pipe 3 is mounted on the thermal plate 11, the efficiency of heat dissipation of the air guide heat sink 10 is further improved.

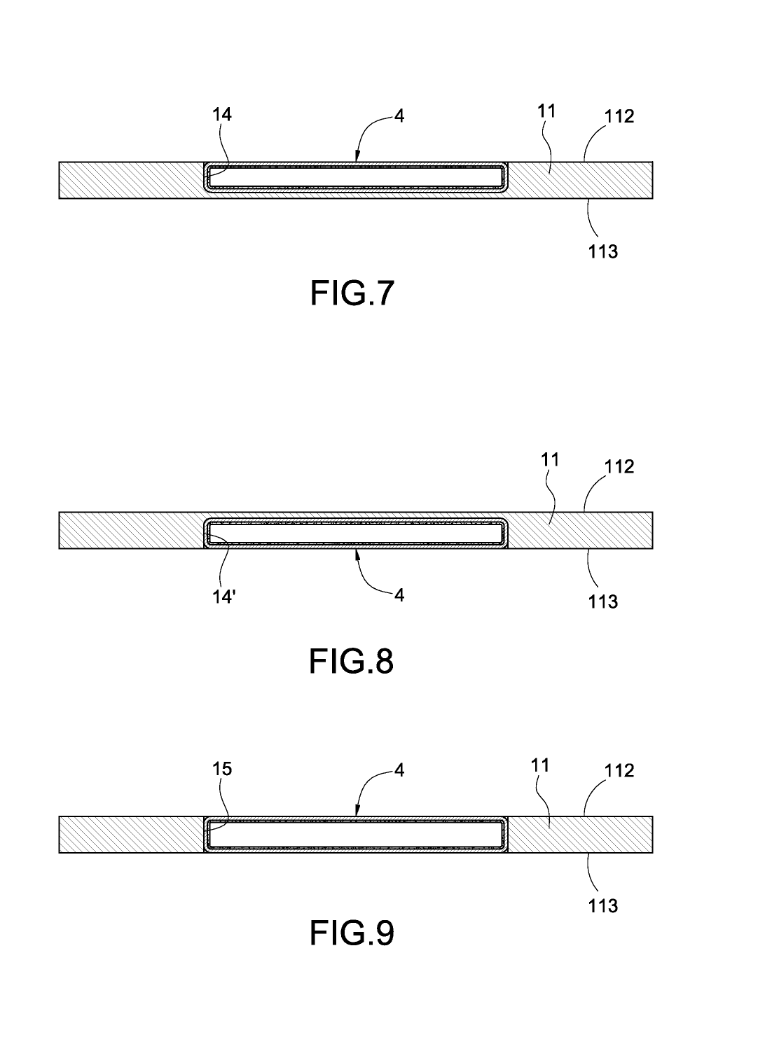

As seen in FIG. 7 to FIG. 9, the air guide heat sinks 10 of the fifth, sixth and seventh embodiments are similar to that of the first embodiment except that the air guide heat sinks 10 further comprises a vapor chamber 4.

In the air guide heat sink 10 of the fifth embodiment as shown in FIG. 7, the thermal plate 11 has a top surface 112 and a recess 14 is formed on the top surface 112. The vapor chamber 4 is mounted on the recess 14. In the air guide heat sink 10 of the sixth embodiment as shown in FIG. 8, the thermal plate 11 has a bottom surface 113 and a recess 14′ is formed on the top surface 112. The vapor chamber 4 is mounted on the recess 14′.

In the air guide heat sink 10 of the seventh embodiment as shown in FIG. 9, the thermal plate 11 has a top surface 112 and a bottom surface 113. A through groove 15 penetrating the top surface 112 and the bottom surface 113 is formed on the thermal plate 11 while the vapor chamber 4 is mounted on the through groove 15. Since the vapor chamber 4 is mounted on the thermal plate 11, the efficiency of heat dissipation of the air guide heat sink 10 is further improved.

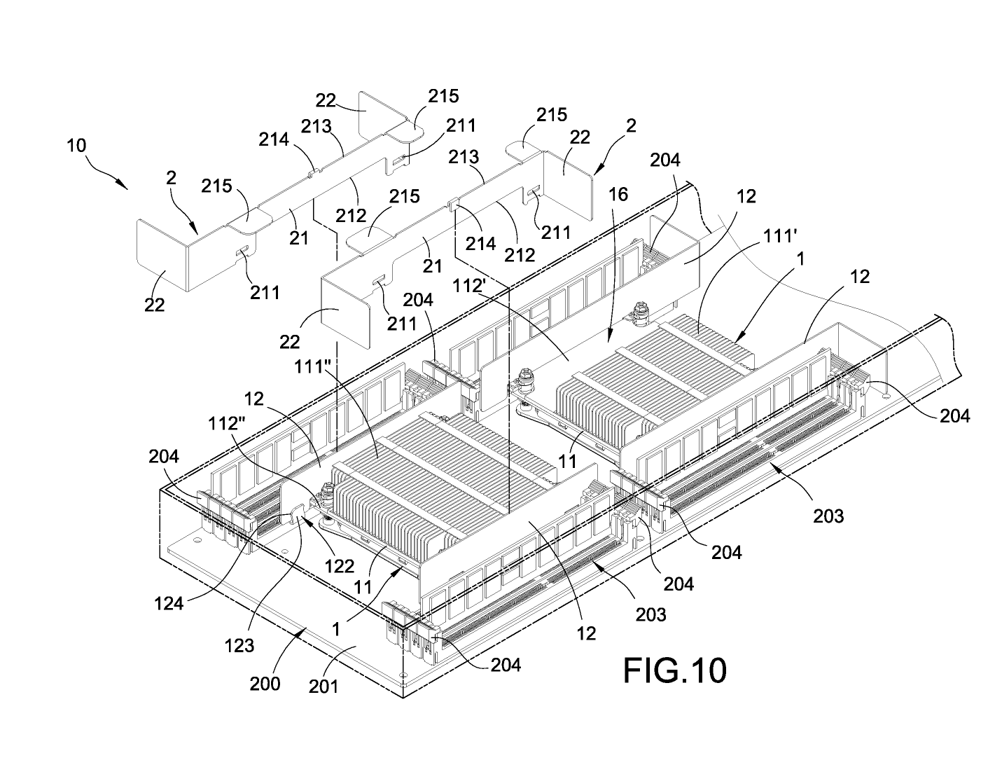

Referring to FIG. 10 to FIG. 14, the disclosure further provides an air guide cooling module 100 mainly comprising two bases 1 and a pair of U-shaped air guide members 2.

Each base 1 comprises a thermal plate 11 and a pair of air guide plates 12 connected to and fixed to opposite two sides of the thermal plate 11. Two bases 1 are arranged side by side. One of the two bases 1 is connected with a plurality of first fins 111′ while the other one is connected with a plurality of second fins 111″. Each first fin 111′ is connected to one thermal plate 11 while each second fins 111″ is connected to the other thermal plate 11. The pair of air guide plates 12 each has a connection portion 122.

Specifically, each connection portion 122 comprises one or multiple elastic pieces 123 which extend from the air guide plate 12 and are folded. Each elastic piece 123 has a protruding portion 124 and is arranged on the inner side of the air guide plate 12. That is, each elastic piece 123 is arranged on one side of the air guide plate 12 near the fins 111.

Moreover, one thermal plate 11 has a first top surface 112′ and each first fin 111′ is connected to a part of the first top surface 112′. The first top surface 112′ forms a no-fin area 16 among each first fin 111′ and one air guide plate 12, while the other thermal plate 11 has a second top surface 112″. Each second fin 111″ is connected to the whole of the second top surface 112″.

The pair of the U-shaped air guide members 2 is detachably connected to one of the bases 1. The two U-shaped air guide members 2 and the base 1 surround and form an air guide channel 13. Each U-shaped air guide member 2 has a vertical plate 21 and two horizontal plates 22 bending and extending from two ends of the vertical plate 21 towards a direction away from the base 1. Each vertical plate 21 and each connection portion 122 are connected with each other.

Furthermore, one or multiple fastening grooves 211 are formed on each vertical plate 21. Each protruding portion 124 and each fastening groove 211 are fastened with each other while each vertical plate 21 has a bottom end 212 and a top end 213. Each fastening groove 211 is formed near the bottom end. Each top end 213 extends towards the air guide plate 12 and folds to form one or multiple hooks 214. Each hook 214 and each air guide plate 12 are fastened with each other. The angle θ1 between each vertical plate 21 and the horizontal plate 22 ranges from 90 degrees to 150 degrees. In this embodiment, the optimal angle θ1 between each vertical plate 21 and the horizontal plate 22 is 90 degrees.

Moreover, each top end 213 extends towards the inner side of each of the vertical plates 21 and forms a handle portion 215. That is, each top end 213 extending towards the fins 111 to form the handle portion 215.

The assembly of the air guide cooling module 100 involves two bases 1 arranged side by side, wherein one of the two bases 1 is connected with multiple first fins 111′ while the other is connected with multiple second fins 111″; the pair of U-shaped air guide members is detachably connected to one of the bases 1 and two U-shaped air guide members 2 and the base 1 surround and form the air guide channel 13; Each U-shaped air guide member 2 has the vertical plate 21 and two horizontal plates 22 bending and extending from two ends of the vertical plate 21 towards a direction away from the base 1. Thereby, the base 1 and the U-shaped air guide members 2 may be assembled together or be separated from each other.

As a result, the air guide cooling module 100 may be installed on the motherboard 200 with electronic components densely disposed thereon. Additionally, the base 1 and the U-shaped air guide member 2 can guide airflow into the air guide channel 13 such that the air guide cooling module 100 may receive maximum airflow. This improves the efficiency of heat dissipation of the air guide cooling module 100.

In the use state of the air guide cooling module 100, it is used with a motherboard 200 and a fan 300. The motherboard 200 comprises a circuit board 201, two CPUs 202 arranged side by side on the circuit board 201 and four memory slot groups 203 disposed on two sides of each CPU 202. Two ends of each memory slot group 203 have two pull blocks 204. The fan 300 is arranged depending on the motherboard 200.

Firstly, as shown in FIG. 10 to FIG. 12, the two bases 1 are fixed above each CPU 202 and between two memory slot groups 203 while the air guide plate 12 is arranged along the inner side of the memory slot groups 203.

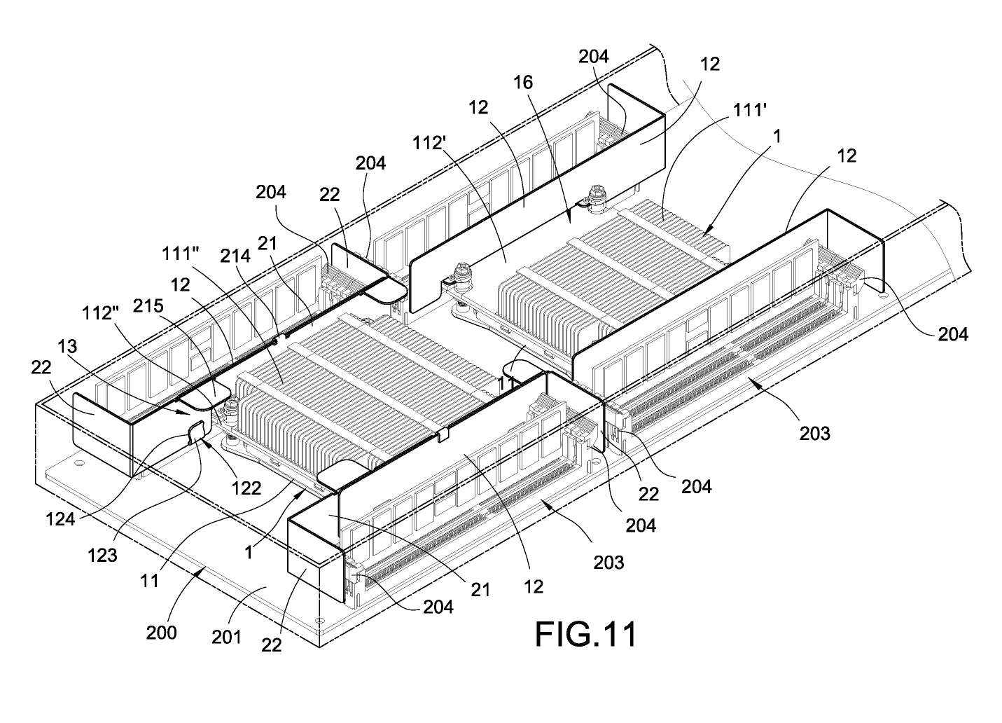

Referring to FIG. 10 to FIG. 11, the pair of the U-shaped air guide members 2 then is detachably connected to one of the bases 1. Each protruding portion 125 is fastened with each fastening groove 211 so each vertical plate 21 is detachably connected to the connection portion 122, wherein the two horizontal plates 22 are disposed between each two memory slot groups 203.

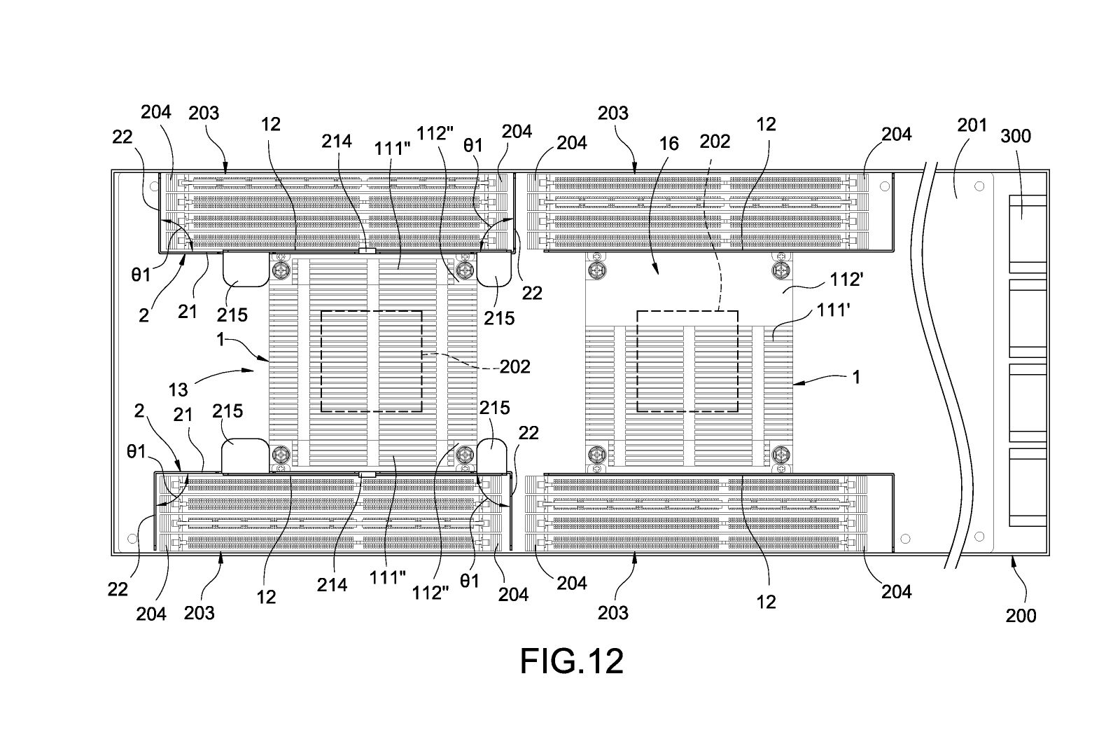

Lastly, as seen in FIG. 12, the fan 300 and the air guide channel 13 are arranged correspondingly and the U-shaped air guide members 2 fill the gap between each memory slot group 203. This ensures that airflow is guided into the air guide channel 13 and airflow brings heat of CPU 202 to the first fins 111′ and the second fins 111″ in order to dissipate the heat out.

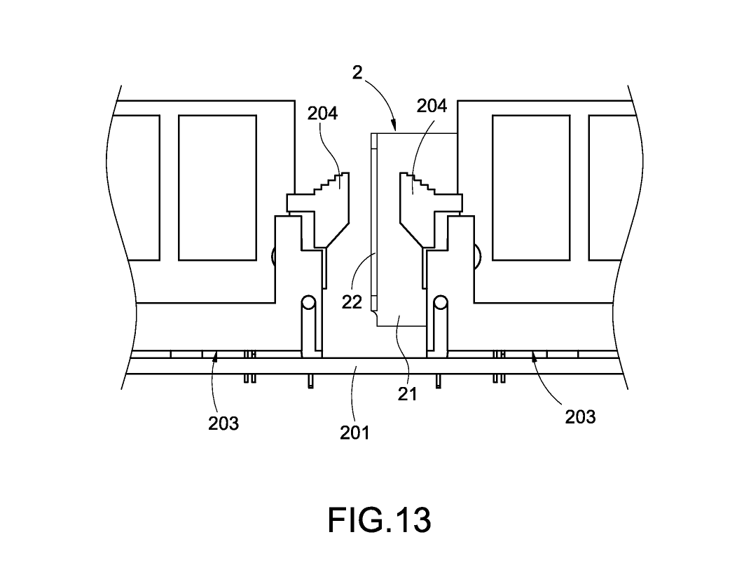

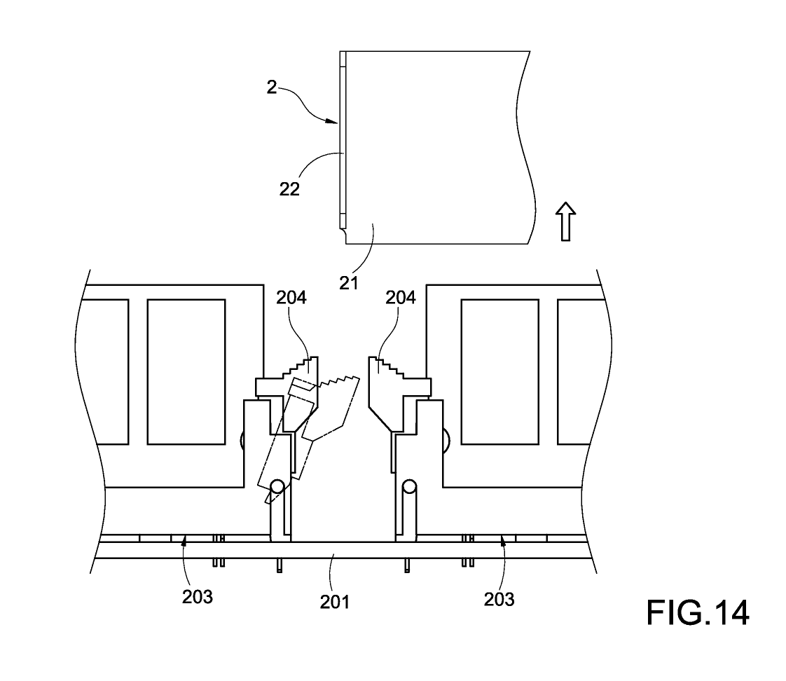

On the other hand, as shown in FIG. 12 and FIG. 13, nowadays the motherboard 200 is made quite small so the CPU 202 and the memory slot groups 203 are arranged even more densely. The gaps between the memory slot groups 203 is just enough for the width of the horizontal plate 22 to be plugged into but the pull block 204 cannot be pulled. However, as shown in FIG. 14, the U-shaped air guide members 2 can be assembled to or disassembled from the base 1 so it can be removed from the base 1, thereby enabling the pull block 204 to be used properly.

Additionally, as seen in FIG. 12, the fan 300 may be arranged near the first fins 111′ or near the second fins 111″, and the disclosure is not limited to this embodiment. Whether the fan 300 is near the first fins 111′ or near the second fins 111″, the fan 300 generates airflow blowing from the first fins 111′ to the second fins 111″. The first top surface 112′, therefore, forms a no-fin area 16 between each first fin 111′ and one of the air guide plates 12. This ensures airflow successfully flows from the first fins 111′ to the second fins 111″, thereby improving the performance of air guidance and the efficiency of heat dissipation regarding the air guide cooling module 100.

Similarly, when the fan 300 generates airflow blowing from the second fins 111″ to the first fins 111′, the second top surface 112″ forms a no-fin area between each second fin 111″ and one of the air guide plates 12. This ensures airflow successfully flows from the second fins 111″ to the first fins 111′.

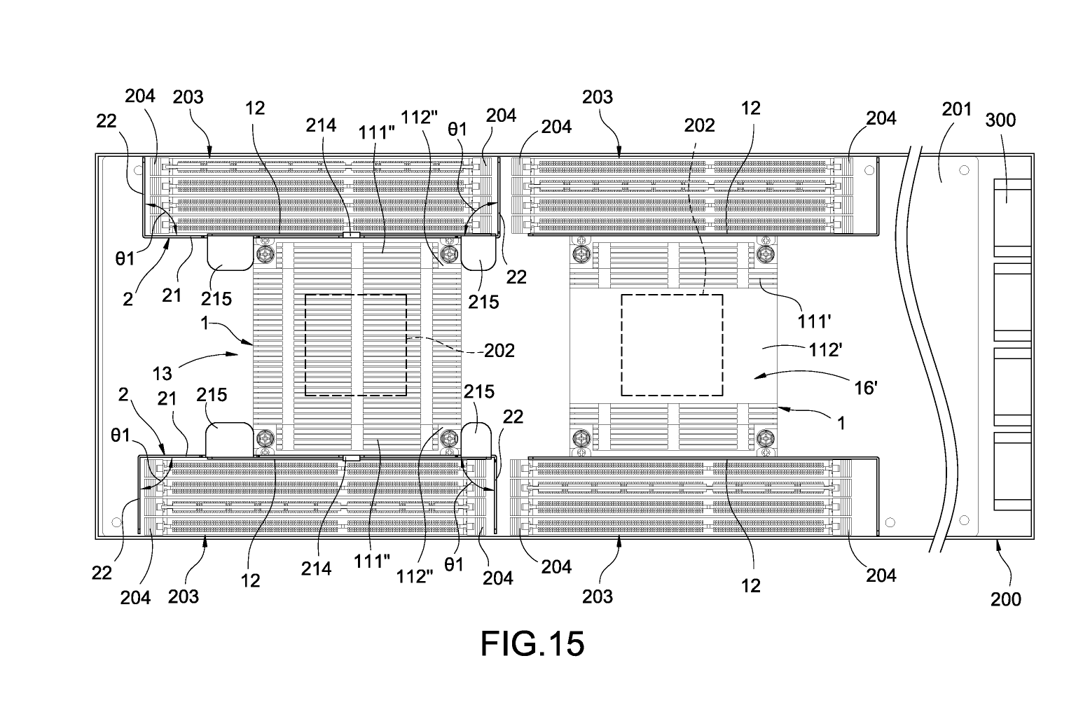

Referring to FIG. 15, the air guide cooling module 100 of the second embodiment is similar to that of the first embodiment except that the position of the no-fin area 16′ is different.

Specifically, the fan 300 generates airflow blowing from the first fins 111′ to the second fins 111″ so each first fin 111′ is connected to two sides of the first top surface 112′. The first top surface 112′ forms a no-fin area 16′ between each first fin 111′ while each second fin 111″ is connected to the whole of the second top surface 112″. This ensures airflow goes from the first fin 111′ to the second fins 111″.

Similarly, when the fan 300 generates airflow blowing from the second fins 111″ to the first fins 111′, the second top surface 112″ also forms a no-fin area between each second fin 111″. Hence, airflow may go from the second fin 111″ to the first fins 111′.

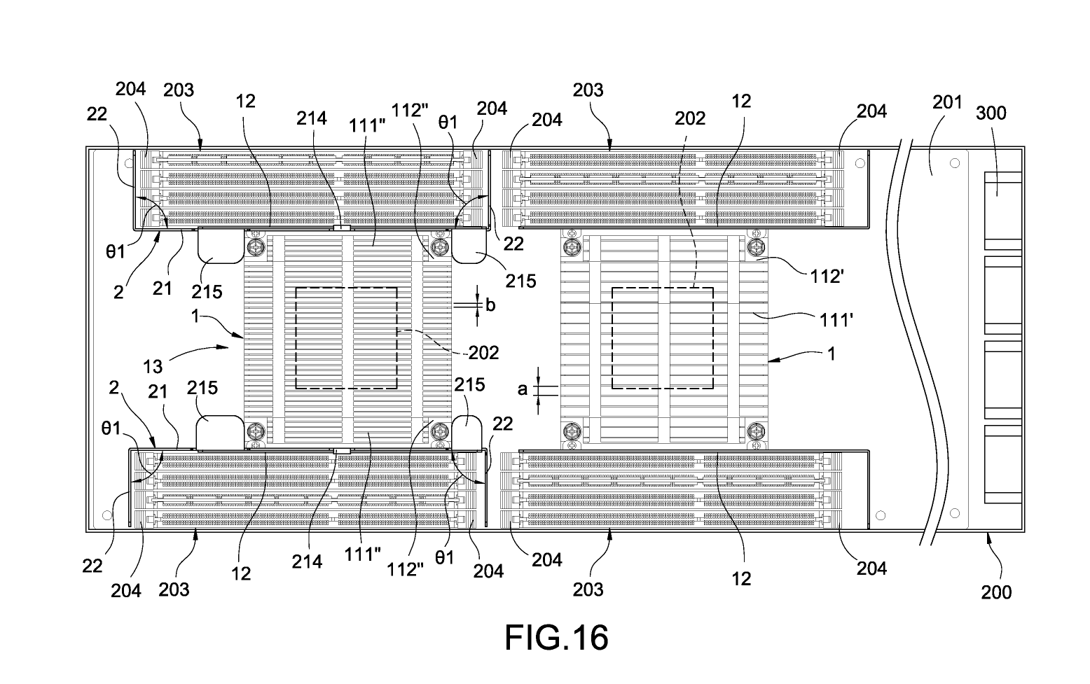

Referring to FIG. 16, the air guide cooling module 100 of the third embodiment is similar to that of the first embodiment except that the distance a between each first fin 111′ is greater than the distance b between each second fin 111″.

The fan 300 generates airflow blowing from the first fins 111′ to the second fins 111″ so each first fin 111′ are spaced apart and connected to the whole of the first top surface 112′. Each second fin 111″ is spaced apart and connected to the whole of the second top surface 112″. The distance a between each first fin 111′ is greater than the distance b between each second fin 111″. Thereby, the airflow is able to blow from the first fins 111′ to the second fins 111″.

Similarly, when the fan 300 generates airflow blowing from the second fins 111″ to the first fins 111′, the distance a between each first fin 111′ is less than the distance b between each second fin 111″. Thereby, the airflow is able to blow from the second fins 111″ to the first fins 111′.

To sum up, the air guide cooling module and the air guide heat sink are novel, non-obvious to the person skilled in the art and industrially applicable, and the disclosure is not publicly known prior to the filing of the patent application. Thus, the disclosure complies with patent laws and is filed accordingly.

What is claimed is:

1. An air guide heat sink, comprising:
a base connected with a plurality of fins; and
a pair of U-shaped air guide members detachably connected to the base, wherein the pair of U-shaped air guide members and the base surround and form an air guide channel, each of the U-shaped air guide members has a vertical plate and two ends of the vertical plate extend towards a direction away from the base and form two horizontal plates.

2. The air guide heat sink according to claim 1, wherein the base comprises a thermal plate and a pair of air guide plates fixed to opposite two ends of the thermal plate, the fins are connected to the thermal plate, the pair of the air guide plates each has a connection portion and each of the vertical plates and each of the connection portions are connected with each other.

3. The air guide heat sink according to claim 2, wherein each of the connection portions comprises at least one elastic piece extending from the air guide plate and being folded, each of the elastic pieces has a protruding portion, at least one fastening groove is formed on each of the vertical plates while each of the protruding portions and each of the fastening grooves are fastened with each other.

4. The air guide heat sink according to claim 3, wherein each of the elastic pieces is arranged on an inner side of the air guide plate.

5. The air guide heat sink according to claim 3, wherein each of the vertical plates has a bottom end and a top end, each of the fastening grooves is formed near the bottom end, each of the top ends extends towards the air guide plate and folds to forms a least one hook, and each of the hooks and each of the air guide plates are fastened with each other.

6. The air guide heat sink according to claim 1, wherein each of the vertical plates has a top end and each of the top ends extends towards an inner side of each of the vertical plates to form a handle portion.

7. The air guide heat sink according to claim 1, wherein an angle between each vertical plate and each horizontal plate ranges from 90 degrees to 150 degrees.

8. An air guide cooling module, comprising:
two bases arranged side by side, wherein one of the two bases is connected with a plurality of first fins while the other is connected with a plurality of second fins; and
a pair of U-shaped air guide members detachably connected to one of the two bases, wherein the pair of U-shaped air guide members and one of the two bases surround and form an air guide channel, each of the U-shaped air guide members has a vertical plate and two ends of the vertical plate extend towards a direction away from one of the two bases and form two horizontal plates.

9. The air guide cooling module according to claim 8, wherein each of the bases comprises a thermal plate and a pair of air guide plates fixed to opposite two ends of the thermal plate, the first fins are connected to one of the thermal plates while the second fins are connected to the other thermal plate, the pair of the air guide plates each has a connection portion and each of the vertical plates and each of the connection portions are connected with each other.

10. The air guide cooling module according to claim 9, wherein each of the connection portions comprises at least one elastic piece extending from the air guide plate and folded, each of the elastic pieces has a protruding portion, at least one fastening groove is formed on each of the vertical plates while each of the protruding portions and each of the fastening grooves are fastened with each other.

11. The air guide cooling module according to claim 10, wherein each of the elastic pieces is arranged on an inner side of the air guide plate.

12. The air guide cooling module according to claim 10, wherein each of the vertical plates has a bottom end and a top end, each of the fastening grooves is formed near the bottom end, each of the top ends extends towards the air guide plate and folds to form a least one hook, and each of the hooks and each of the air guide plates are fastened with each other.

13. The air guide cooling module according to claim 8, wherein each of the vertical plates has a top end and each of the top ends extends towards an inner side of each of the vertical plates to form a handle portion.

14. The air guide cooling module according to claim 8, wherein an angle between each vertical plate and each horizontal plate ranges from 90 degrees to 150 degrees.

15. The air guide cooling module according to claim 9, wherein one of the thermal plates has a first top surface, the first fins are connected to a part of the first top surface, the first top surface forms a no-fin area between the first fins and one of the air guide plates, the other thermal plate has a second top surface while the second fins are connected to the whole of the second top surface.

16. The air guide cooling module according to claim 9, wherein one of the thermal plates has a first top surface, the first fins are connected to two sides of the first top surface, the first top surface forms a no-fin area among the first fins, the other thermal plate has a second top surface while the second fins are connected to the whole of the second top surface.

17. The air guide cooling module according to claim 9, wherein one of the thermal plates has a first top surface, the first fins are spaced apart from each other and are connected to the whole of the first top surface. The other thermal plate has a second top surface, the second fins are spaced apart from each other and are connected to the whole of the second top surface, and the distance between the adjacent two first fins is greater than the distance between the adjacent two second fins.
